(19) United States
(12) Patent Application Publication
(10) Pub. No.: US 2004/0104736 A1
(43) Pub. Date: Jun. 3, 2004

(54) Apparatus and method for analysing fluids

(76) Inventors: Emanuel Cohen, Manchester (GB); Nasr-Eddine Djennati, Manchester (GB)

Correspondence Address: QUARLES & BRADY STREICH LANG, LLP, ONE SOUTH CHURCH AVENUE, SUITE 1700, TUCSON, AZ, 85701-1621, US

(21) Appl. No.: 10/471,504

(22) PCT Filed: Mar. 13, 2002
(86) PCT No.: PCT/GB02/01040

(30) Foreign Application Priority Data
Mar. 13, 2001 (GB) 0106250.4

(51) Int. Cl. G01R 27/08

(52) U.S. Cl. 324/692

(57) ABSTRACT

Apparatus for analysing fluids, especially body fluids and blood, includes means for applying an oscillating electric field 1 to a sample of fluid and means for measuring electrical current flowing in the sample being analysed as a result of application of the applied field to enable the loss factor of an electrical circuit in which the sample is comprised to be determined. Changes in the loss factor with the frequency of field applied can be determined and by comparison with stored data, used to identify the presence and concentration of substances in a fluid. The apparatus may be arranged to analyse blood in a living body.

### RELATED APPLICATIONS

This application claims the priority of PCT International Patent Application No. PCT/GB02/01040, filed Mar. 13, 2002, which is based on U.K. Patent Application No. 0106250.4, filed Mar. 13, 2001.

### FIELD OF THE INVENTION

The present invention relates to an apparatus and method for analysing body fluids particularly, although not exclusively, blood, and for determining the presence and concentration of various substances in such fluids.

### BACKGROUND OF THE INVENTION

Analysis of blood is widely practised in the medical treatment and diagnosis of humans and animals. A plurality of methods are known for analysing blood. Embodiments of the present invention seek to provide an alternative method of analysing blood.

Conventionally it is necessary for a sample of blood to be removed from a living body for analysis outside the body. This can be unpleasant and inconvenient, especially if frequent analysis of blood is required such as can be the case for a sufferer of diabetes where frequent analysis of the concentration of glucose in their blood is necessary.

Embodiments of the present invention seek to provide an apparatus and method for non-invasive analysis of blood in the body.

### SUMMARY OF THE INVENTION

According to an aspect of the present invention there is provided apparatus for analysing body fluids in vivo, the apparatus comprising an electrical oscillator electrically connected to electrode means adapted for wearing on a human or animal body, the electrical oscillator and electrode means being operative to apply an oscillating electric field to a fluid comprised in the body, the electrode means comprising two electrodes each electrode being associated with an electrical insulator which in use serves to electrically insulate the electrode from a body on which the electrode means is worn, the apparatus further comprising means for measuring electrical current flowing in a fluid being analysed as a result of the applied electrical field to enable the loss factor and power factor of an electrical circuit in which the fluid being analysed is comprised to be determined, means for storing information, means for comparing the measured power factor of the fluid being analysed with stored information in order to determine the presence and concentration of one or more substances in the sample and means to output information relating to the identified substance or substances to a user.

According to another aspect of the present invention there is provided a method of analysing body fluids comprising the steps of: applying an oscillating electric field to a sample of fluid to be analysed by means of insulated electrodes and measuring electrical current flowing in the sample as a result of application of the electric field to enable the loss factor and power factor of an electrical circuit in which the sample is comprised to be determined comparing the measured power factor with stored information to determine the presence and concentration of one or more substance in the sample.

The loss factor of a circuit in which a sample is comprised is related to the dielectric constant of the sample. The dielectric constant of a sample may vary with its constituents. Thus, measurement of the loss factor can enable the presence and concentration of substances present in a fluid to be determined. This is explained more fully below.

Preferably the fluid is a body fluid, especially blood.

The electrodes may be adapted for wearing on a blood rich part of a person's body, for example an earlobe. In one embodiment the electrodes are comprised in a clip arranged to fit on a person's earlobe so that one electrode contacts each side of the person's earlobe. In another embodiment the electrodes are comprised in a garment.

Preferably the means for applying an electric field is operative to produce an oscillating electric field of variable frequency, and current flowing in the sample being analysed is measured when different field frequencies are being applied. In one arrangement the apparatus varies the frequency of the applied field through a range. The range may extend from the order of kilohertz to the order of gigahertz. With this arrangement the current is preferably monitored throughout the range. In one embodiment the frequency range is from 0-500 megahertz.

A range of frequencies enables different substances contained in blood and other fluids to be identified.

Variations in the dielectric constant (as indicated by variations in the power factor) of a sample with variations in frequency of an applied electric field are indicative of the presence and concentration of substances in the sample. Where a range of frequencies is applied to a sample the apparatus may compare the measured power factor over the range of applied field frequencies with stored information thereby to associate features of the measured power factor with the presence of substances in the sample. The apparatus may output information relating to identified substances to a user by means of a visual display. The information may relate to absolute concentration of identified substances, and/or may simply indicate the presence of, or a particular concentration of, a particular substance.

In order that the invention may be more clearly understood embodiments thereof will now be described, by way of example, with reference to the accompanying drawings in which:

### BRIEF DESCRIPTION OF THE DRAWINGS

FIG. 1 shows apparatus according to the invention;

FIG. 2 shows a schematic circuit diagram of the apparatus of FIG. 1;

FIG. 3 is a graph of dielectric constant against frequency for a given material;

FIG. 4 is a vector diagram of conduction and displacement current;

FIG. 5 is a graph of loss factor against frequency for blood;

FIG. 6 is a representation of the display of the apparatus of FIG. 1; and

FIG. 7 is a schematic block diagram of an alternative embodiment of apparatus according to the invention.

FIG. 8 illustrates a preferred embodiment of the electrode structures.

FIG. 9 schematically illustrates an alternative embodiment of the invention.

### DETAILED DESCRIPTION OF THE PREFERRED EMBODIMENTS

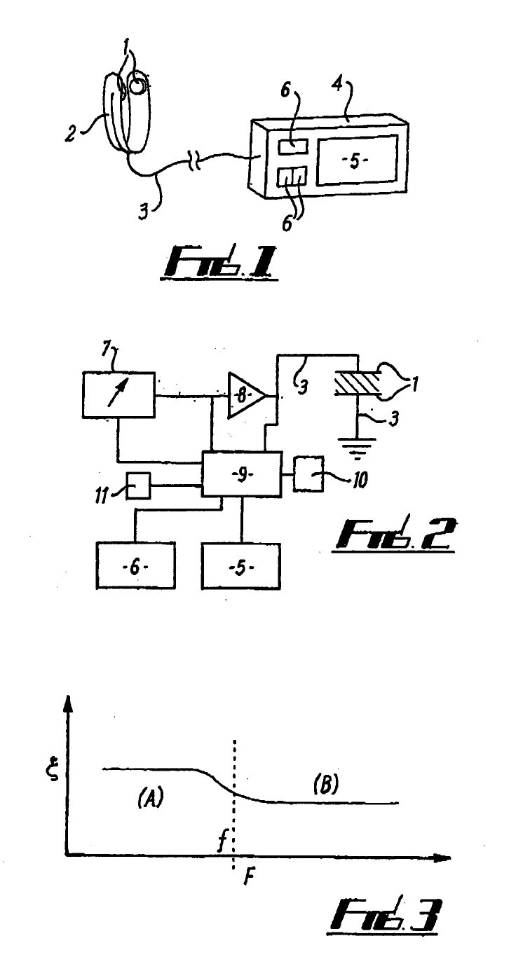

Referring to FIGS. 1 and 2, the apparatus comprises two electrically conductive electrodes 1 mounted facing each other at the free ends of two arms of a resilient U-shaped clip 2. The electrodes are covered in an electrically insulating material, such that no electrically conductive part of the electrodes is exposed. The clip 2 is formed from an electrically insulating plastics material and is arranged to be comfortably fitted onto a person's earlobe so that the two electrodes 1 are disposed on opposite sides respectively of the person's earlobe.

The electrodes 1 are connected, by way of an electrical lead 3, to a control unit 4. The control unit 4 comprises a housing having a display 5 and various user operable controls 6 on the outside and contains electronic circuitry 7,8,9 and an associated power supply 10. The housing is sized to be able to be conveniently held in a user's hand.

The electronic circuit comprises a variable frequency oscillator 7, and amplifier 8, microprocessor 9 and memory 11. The variable frequency oscillator 7 is operative to produce a substantially sinusoidal alternating electrical signal of variable and controllable frequency within the range of a few kilohertz to a few gigahertz. The amplifier 8 is operative to amplify that signal for transmission to the electrodes 1. The microprocessor 9 is operative to control the oscillator 7, to analyse current flowing between the electrodes 1, to process this information and to provide an output to a user via the display 5. The microprocessor 9 is also arranged to respond to instructions input by a user by means of the user operable controls 6. The memory stores information and instructions for use by the microprocessor 9.

The apparatus is thus able to subject a material placed between the electrodes 1 to an alternating electric field, and to analyse any current flowing in that material as a result of the applied electric field. Where the material placed between the electrode has some dielectric property, such as a person's earlobe containing blood, the combination of the electrodes and material forms a capacitor. The nature of the flow of current in the capacitor as a result of an applied alternating electric field will depend upon characteristics of the material, in particular its dielectric constant ξ. This depends upon the structure of a particular material, in particular constituents of the material carrying an electrical charge or dipole and the manner in which those constituents respond to an alternating electrical field.

Blood and substances of interest that may be found in it typically comprise molecules having permanent electrical dipoles. Under the influence of an applied electric field each dipole will be subject to a force tending to orient it in the direction of the field and it can be realised that the resultant movements of the kinked and curled chain may be very complicated. In addition, electrons, atoms, and molecules will have a different behaviour to an applied field of varying frequency. The time taken for a dipole to orient itself to an electric field and for atoms and molecules to respond to an electrical field is dependent upon the nature of the individual dipole (molecule), atom or molecule in question. As a result the extent of dipole polarisation taking place for a given dipole will vary with the frequency of the applied field. The extent of polarisation affects the dielectric constant (ε) of a material. Thus it will be seen that for a material such as blood the dielectric constant will change with frequency of an applied electric field.

FIG. 3 shows how the dielectric constant (ε) varies with the frequency F of an electric field applied to a dielectric material containing a species of molecule having a permanent electric dipole. In region A (low frequency) all three components of polarisation are operative, i.e. the electronic, atomic and molecular polarisations can immediately respond to low variations of applied electric field and can orient themselves accordingly. But for frequencies in excess of a value which is characteristic of the size of the dipoles and of the environment in which they are situated, the dipoles become incapable of following the field variations and their contribution to the total polarisation disappears. Thus in region B (high frequency) only the electronic and atomic polarisation components are significant, f representing the frequency at which these changes occur.

A consequence is a gradual change in the dielectric constant of the material as the applied frequency is increased through f.

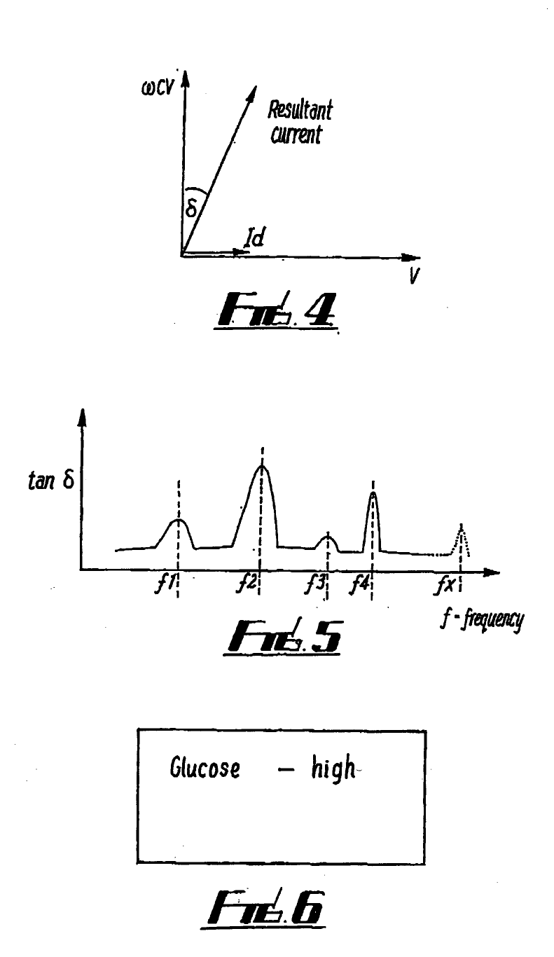

With this variation of dielectric constant with frequency is associated a loss of energy. This “dielectric loss” represents energy extracted from the circuit providing the electric field and converted into heat in the sample material. It is conveniently expressed in terms of a so-called “loss angle” δ. In the absence of dielectric loss the current flow in the capacitor of FIG. 2 will be in phase quadrature with the applied voltage (that is so say 90° out of phase) of magnitude ωCV (where ω=2πf and f is the applied frequency in HZ; C the capacitance, and V the applied voltage).

Where dielectric loss occurs though there is a component of current “Id” in phase with the applied field. The result is that the phase of the total (resultant) current is displaced from perfect phase quadrature by an angle δ. This is illustrated in FIG. 4. Sin δ (which is substantially equivalent to tan δ for small values of δ) is known as the power factor and represents the proportion of the apparent power applied to the capacitor formed by the electrodes and sample material converted to heat in the material.

It is the power factor that is measured and derived by the microprocessor of the apparatus according to the invention. Measurement of the power factor for a given capacitor is well understood and readily achievable using a conventional Q-meter (Q=quality factor).

By measuring the power factor of a material over a range of frequencies it is possible to identify the presence of constituents of the material which affect the power factor at known frequencies.

FIG. 5 shows an illustrative plot of power factor (tan 6) against frequency of applied electric field for a blood sample made by attaching the electrodes 1 of the apparatus of FIGS. 1 and 2 to a person's earlobe. The peaks in the plot represent a sharp increase in the power factor at certain frequencies indicative of the presence of certain substances in the blood, for example, f1 shows the presence of creatine, f2 Glucose, f3 high density lipids (cholesterol), f4 low density lipids. Many other substances can be identified this way, as signified by fx.

It is possible to determine the appropriate frequency or frequency range for a particular substance empirically.

This method also enables the concentration of a particular substance in blood to be determined, the concentration affecting the size of the peak. This can also be determined empirically.

In use the microprocessor 8 is operative to cause the oscillator 7 to produce an alternating electrical signal the frequency of which varies gradually from a few KHz to a few GHz. This signal, suitably amplified, is applied via the electrodes 1 to a person's earlobe. As the frequency of the signal varies the microprocessor monitors the current flowing between the electrodes and calculates the power factor for the circuit. The apparatus then stores (in the memory 11) the value of the power factor in relation to the frequency of the driving signal at which the power factor at which it was measured. This information is then compared by the microprocessor 9 with information stored by the memory 11 relating to the characteristic frequency at which a peak in the power factor would be expected to occur to indicate presence of a certain substance or substances of interest. If a peak in the power factor is found in the collected data at any of these frequencies this is indicative of the presence of a substance of interest. The size of the peak is then compared with stored information to determine a value for the concentration of the identified substances.

The results of analysis are then displayed on the display 5 for a user. Any suitable form of display may be used but conveniently the display shows the name of a substance identified along with an indication of its concentration, as shown in FIG. 6. The concentration could be shown as a numerical value or as falling in one of a number of predetermined ranges, for example high, medium and low.

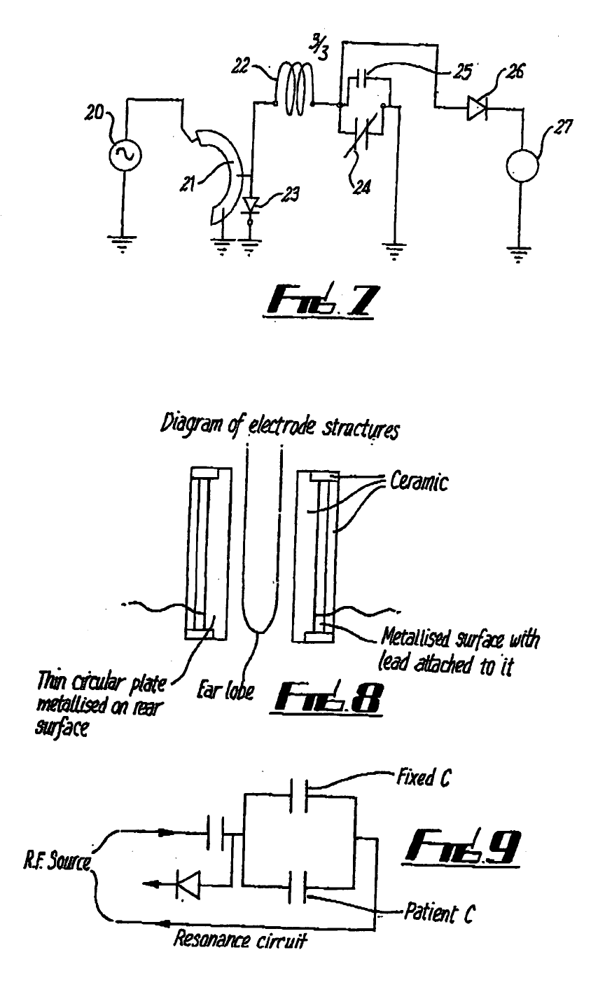

Another embodiment is illustrated by FIG. 7. Referring to this Figure it comprises a wide band variable oscillator 20 for providing an alternating electrical signal via a wide metallic strip 21 (for providing a low impedance output over a wide frequency range) to a test coil 22, and is also connected to earth via a diode 23. The test coil 22 is connected in series to a variable capacitor 24, an experimental capacitor 25, comprising two electrodes and a sample of blood for analysis, and a diode 26. The diode 26 is connected to earth via a Q-meter 27 for determining the dielectric loss of the sample comprised in capacitor 25. The apparatus enables a fluid sample to be subjected to an oscillating electric field and for current flowing in the sample as a result of the field to be analysed and the power factor of the capacitor 25 comprising the sample to be determined in order to analyse the sample.

Although primarily concerned with measuring dielectric loss caused by molecules having a permanent dipole contained in a sample, the apparatus and method could equally be used to measure dielectric loss caused by other constituents of a sample, for example atoms and individual electrons.

The above embodiments facilitate convenient, quick, non-invasive, analysis of fluids especially blood in a living human or animal body and are particularly suited for determining the concentration of glucose in blood.

Single or complex compounds present in blood and other fluids may be analysed. In blood the analyte might be glucose, creatine, cholesterol or other indicators of general or specific health or clinical conditions. The apparatus may comprise its own power supply.

The data captured by the apparatus is transmissible by RF, modem, IR or any other digital or analogue transmission media and can be stored and used comparatively with other data captured by the same or other methods. The data comparison made thereby may be undertaken continuously or periodically. The output of the apparatus may be used to control other apparatus for example, automated drug delivery and automated alert systems. The device provides a direct measurement of the analyte in situ. The device can measure in both static and moving fluids and measure both indigenous and non-indigenous analytes within a sample.

In a further embodiment and exemplification the following may be envisaged. The lobe of the ear consisting only of soft tissue and devoid of muscle, ligaments, tendons or a skeletal bone structure is particularly suitable as a test site. The equivalent of circular metallic plates measuring in diameter from 5 mm to 10 mm are disposed on either side of the ear lobe but are insulated from the latter. Such metallic plates can typically be a metallic coating on a thin ceramic disc (the latter possessing a very low dielectric loss). Such structures can be made industrially only 250 microns or less and can be inserted and fixed to one opening of a ceramic annulus of thickness 1-2 mm (see diagram). A wire (suitably insulated) can be soldered to the metallised area. A third ceramic component containing a circular aperture is located behind the metallised area with the insulated wire conductor passing through the aperture. The whole structure will form a rigid electrode configuration which will have a long life time, and will be sealed being impervious to body fluids e.g. sweat, urine, faeces. A second electrode configuration is disposed on the other side of the earlobe. Both electrode configurations are supported by a light-weight structure which allows the distance between the two electrodes to be varied according to the size of the patient's earlobes. The electrodes should be clamped firmly and securely to the earlobe but not excessively so, the actual pressure being determined by patient comfort. Prior to fixing, the earlobe should be cleaned and the skin surface degreased by a patented grease solvent. It is envisaged that the total weight of the electrode appendages and support will not exceed a few grammes. Also behind the earlobe and supported by the top and rear of the ear is a small plastic compartment containing a fixed high Q capacitor and a high Q coil, the latter being formed by a helical metallised coil deposited on a ceramic cylindrical former or alternatively a flat helical metallised coil deposited on a thin flat ceramic plate. The ear area thus contains three electrical components which are connected to form a series resonant circuit. A fourth electrical component of very small size is also included (a semi-conducting high frequency diode) is also included to convert the a.c. voltages developed across the two capacitors into a proportional d.c. voltage. From the total above structure a flexible and thin multi-core cable is led to a small control box which may be free mounting or connected to the patient's body. The control box will house the power supply, a memory, a microprocessor, an amplifier, logic circuits, switches/keyboard and a display and of course availability of spot frequencies the latter being capable of being periodically shifted in frequency slightly by being frequency modulated. It should be stressed that the instrumentation will be more complex and be more suited for a haematologist who requires information on a range of blood analytes than the requirements of a diabetic who only needs information as regards their glucose concentration.

We will consider the requirements of the latter. The patient depresses a button which causes the microprocessor to initiate and instruct a separate oscillator chip to commence oscillations at a predetermined frequency and to be frequency modulated within a narrow band frequency deviation. The d.c. resulting from rectification of the enhanced resonant voltage is conveyed to the d.c. amplifier whose output goes to the memory. The memory also contains pre-recorded information as regards Q values of the resonant circuit when only air is between the capacitor plates for a range of electrode spacings, the particular one being keyed in by the patient and relevant only to himself. The information now available are the values of Q's and capacitances, the latter being stored in memory. The microprocessor then calculates the value of tan δ and selects the peak value which will then be displayed and expressed in mmols/L. Audible notes will be heard if the patient is nearing the hypo or hyper glyceamic state. This further embodiment is illustrated in FIGS. 8 and 9.

The above embodiments are described by way of example only. Many variations are possible without departing from the invention.

1. Apparatus for analysing body fluids in vivo, comprising:
an electrical oscillator electrically connected to electrode means adapted for wearing on a human or animal body, the electrical oscillator and electrode means being operative to apply an oscillating electric field to a body fluid, wherein the electrode means comprises two electrodes with each electrode being associated with an electrical insulator that serves to electrically insulate each electrode from the human or animal body on which the electrode means is worm,
means for measuring electrical current flowing in said body fluid as a result of the oscillating electric field to enable measurement of a loss factor and a power factor of an electrical circuit that includes the body fluid being analysed,
means for storing information,
means for comparing the measurement of said power factor of the body fluid being analysed with stored information in order to determine the presence and concentration of one or more substances in the body fluid; and
means to output information relating to an identified substance or substances to a user.

2. Apparatus as claimed in claim 1, wherein the body fluid is blood.

3. Apparatus as claimed in claim 1, wherein the electrodes comprise a clip.

4. Apparatus as claimed in claim 1, wherein the electrodes are comprised in a garment.

5. Apparatus as claimed in claim 1, wherein the electrical oscillator is operative to produce an oscillating electric field of variable frequency, and the means for measuring electrical current is operative to measure current when different field frequencies are being applied.

6. Apparatus as claimed in claim 1, wherein the electrical oscillator is operative to vary the frequency of an applied field through a range and the means for measuring electrical current is operative to measure current when different field frequencies are being applied.

7. Apparatus as claimed in claim 1, wherein the electrical oscillator is operative to vary the frequency of an applied field through a range extending from the order of kilohertz to the order of gigahertz.

8. Apparatus as claimed in claim 1, wherein the electrical oscillator is operative to vary the frequency of an applied field and said field is applied via the same electrodes, irrespective of frequency.

9. Apparatus as claimed in claim 1, wherein the electrical oscillator is operative to produce an oscillating electric field at one or more fixed frequencies.

10. Apparatus as claimed in claim 1, wherein the electrical oscillator is operative to produce an oscillating electric field at a single frequency, the frequency being suitable for determining the concentration of glucose in blood.

11. Apparatus as claimed in claim 1, wherein the two electrodes are arranged, in use, to be disposed on opposite sides respectively of a part of said human or animal body.

12. Apparatus as claimed in claim 1, wherein the apparatus controls an automated drug delivery system.

13. Apparatus as claimed in claim 1, wherein the electrodes each comprise a metallic coating on a thin ceramic disc.

14. Apparatus as claimed in claim 13, wherein the electrodes each comprise a metallic coating on a thin ceramic disc fixed to a ceramic annulus

15. A method of analysing body fluids, comprising the steps of:
(a) applying an oscillating electric field to a sample of fluid to be analysed by means of insulated electrodes,
(b) measuring electrical current flowing in the sample of fluid as a result of application of the oscillating electric field to enable a loss factor and a power factor of an electrical circuit in which the sample is comprised to be determined; and
(c) comparing the power factor measured with stored information to determine a presence and concentration of one or more substance in the sample of fluid.

16. A method as claimed in claim 15, wherein the sample of fluid is blood.

17. A method as claimed in claim 15, wherein the frequency of an applied field is varied through a range, and the power factor of a circuit in which the sample is comprised is calculated as the frequency is varied.

18. A method as claimed in claim 15, wherein the sample of fluid is analysed in vivo in a human or animal body.
